(19) United States
(12) Patent Application Publication
(10) Pub. No.: US 2024/0234277 A1
(43) Pub. Date: Jul. 11, 2024

(54) SEMICONDUCTOR PACKAGE

(71) Applicant: SAMSUNG ELECTRONICS CO., LTD., Suwon-si (KR)

(72) Inventors: Narae SHIN, Suwon-si (KR); Jeong-Kyu Ha, Suwon-si (KR)

(21) Appl. No.: 18/464,091

(22) Filed: Sep. 8, 2023

(30) Foreign Application Priority Data
Jan. 6, 2023 (KR) 10-2023-0002214

(51) Int. Cl. H01L 23/498; H01L 23/00; H01L 25/065; H05K 1/11

(52) U.S. Cl. CPC H01L 23/49822; H01L 23/49838; H01L 24/32; H01L 24/97; H01L 25/0655; H05K 1/111; H01L 2224/32137; H01L 2224/32225; H01L 2224/97; H01L 2924/182

(57) ABSTRACT

A semiconductor package includes a base film that has peripheral regions extending in a longitudinal direction and an inner region disposed between the peripheral regions and extending in the longitudinal direction. A unit film package is disposed on the inner region of the base film and is defined by a cut line. Dummy patterns are disposed on the peripheral regions of the base film and between the cut line and the opposite ends in the width direction. A first solder resist layer is disposed on the base film and covers the unit film package inside the cut line. In a plan view, the first solder resist layer extends in the width direction, runs across the cut line, and covers the dummy patterns.

### CROSS-REFERENCE TO RELATED APPLICATION

This U.S. nonprovisional application claims priority under 35 U.S.C. § 119 to Korean Patent Application No. 10-2023-0002214, filed on Jan. 6, 2023, in the Korean Intellectual Property Office, the disclosure of which is hereby incorporated by reference in its entirety.

### TECHNICAL FIELD

The present inventive concepts relate to a semiconductor package, and more particularly, to a chip-on-film type semiconductor package.

### DISCUSSION OF THE RELATED ART

In the semiconductor industry, integrated circuit packaging technology has been developed to satisfy requirements for small-form-factor devices and high package reliability. For instance, package techniques capable of achieving a chip-size package are actively being developed to satisfy the requirements for small-form-factor devices, and package techniques capable of promoting efficiency in a package process and increasing mechanical and electrical reliability of a package product have attracted considerable attention in terms of high package reliability.

Chip-on-film (COF) technology is a new type of package that has been developed on a display driver IC with the trend of light, thin, and compact-sized communication equipment. In the chip-on-film (COF) technology, a semiconductor package becomes highly integrated to allow for a display device with a high resolution.

As a semiconductor process becomes finer and includes more elaborate patterns, defects produced on a semiconductor package must be inspected. The inspection of particles on the semiconductor package enhances reliability of the semiconductor package and increases process yield.

### SUMMARY

A semiconductor package includes a base film that has peripheral regions and an inner region disposed between the peripheral regions. The peripheral regions extend in a longitudinal direction. The inner region extends in the longitudinal direction. A unit film package is disposed on the inner region of the base film and is defined by a cut line. Dummy patterns are disposed on the peripheral regions of the base film and between the cut line and the opposite ends in the width direction. A first solder resist layer is disposed on the base film. The first solder resist layer covers the unit film package inside the cut line. The first solder resist layer extends in the width direction, runs across the cut line and covers the dummy patterns.

A semiconductor package includes a base film that extends in a first direction and has a first peripheral region, an inner region, and a second peripheral region that are arranged in a second direction orthogonal to the first direction. The first peripheral region, the inner region, and the second peripheral region extend in the second direction. A unit film package is disposed on the inner region of the base film and is defined by a cut line. A first dummy pattern and a second dummy pattern are respectively provided on the first peripheral region and the second peripheral region of the base film. Each of the first and second dummy patterns is disposed between the cut line and one of opposite ends in the second direction of the base film. A first solder resist layer is disposed on the base film. The first solder resist layer covers the unit film package inside the cut line. A second solder resist layer covers the first dummy pattern on the first peripheral region of the base film. A third solder resist layer covers the second dummy pattern on the second peripheral region of the base film. The second solder resist layer and the third solder resist layer are connected to each other through a first extension part that is spaced apart in the first direction from the cut line, extends in the second direction, and connects the second solder resist layer to the third solder resist layer.

A semiconductor package includes a base film that includes an inner region, a first peripheral region, and a second peripheral region, the inner region extending in a longitudinal direction of the base film. The first peripheral region and the second peripheral region are respectively disposed on opposite ends in a width direction of the base film. A unit film package is disposed on the inner region of the base film and is defined by a cut line. A first dummy pattern is disposed on the first peripheral region of the base film and is disposed between the cut line and one of the opposite ends of the base film. A second dummy pattern is disposed on the second peripheral region of the base film and between the cut line and the other of the opposite ends of the base film. A first solder resist layer is disposed on the base film. The first solder resist layer covers the unit film package inside the cut line. A second solder resist layer covers the first dummy pattern on the first peripheral region of the base film. A third solder resist layer covers the second dummy pattern on the second peripheral region of the base film. The second solder resist layer and the third solder resist layer are connected to each other through an extension part that extends in the width direction. The unit film package includes a mounting region disposed on the inner region and connection regions disposed on opposite ends in the longitudinal direction from the mounting region.

### BRIEF DESCRIPTION OF DRAWINGS

A more complete appreciation of the present disclosure and many of the attendant aspects thereof will be readily obtained as the same becomes better understood by reference to the following detailed description when considered in connection with the accompanying drawings, wherein:

FIG. 1A is a plan view showing a semiconductor package according to some embodiments of the present inventive concepts;

FIGS. 1B and 1C are cross-sectional views respectively taken along lines A-A′ and B-B′ of FIG. 1A;

FIG. 1D is an enlarged plan view showing a unit film package of FIG. 1A;

FIG. 2 is a plan view showing a semiconductor package according to some embodiments of the present inventive concepts;

FIG. 3A is a plan view showing a semiconductor package according to some embodiments of the present inventive concepts;

FIGS. 3B and 3C are cross-sectional views respectively taken along lines A-A′ and B-B′ of FIG. 3A;

FIG. 3D is an enlarged plan view showing a unit film package of FIG. 3A;

FIG. 4A is a plan view showing a semiconductor package according to some embodiments of the present inventive concepts;

FIGS. 4B and 4C are cross-sectional views respectively taken along lines A-A′ and B-B′ of FIG. 4A;

FIG. 4D is an enlarged plan view showing a unit film package of FIG. 4A.

FIG. 5 is a plan view showing a semiconductor package according to some embodiments of the present inventive concepts;

FIG. 6A is a plan view showing a semiconductor package according to some embodiments of the present inventive concepts;

FIGS. 6B and 6C are cross-sectional views respectively taken along lines A-A′ and B-B′ of FIG. 6A;

FIG. 6D is an enlarged plan view showing a unit film package of FIG. 6A;

FIG. 7A is a plan view showing a semiconductor package according to some embodiments of the present inventive concepts;

FIGS. 7B and 7C are cross-sectional views respectively taken along lines A-A′ and B-B′ of FIG. 7A;

FIG. 7D is an enlarged plan view showing a unit film package of FIG. 7A;

FIG. 8 is a plan view showing a semiconductor package according to some embodiments of the present inventive concepts;

FIG. 9 is a plan view showing a semiconductor package module according to some embodiments of the present inventive concepts; and

FIG. 10 is a cross-sectional view showing a semiconductor package module according to some embodiments of the present inventive concepts.

### DETAILED DESCRIPTION OF EMBODIMENTS

The following will now describe a semiconductor package according to the present inventive concepts with reference to the accompanying drawings.

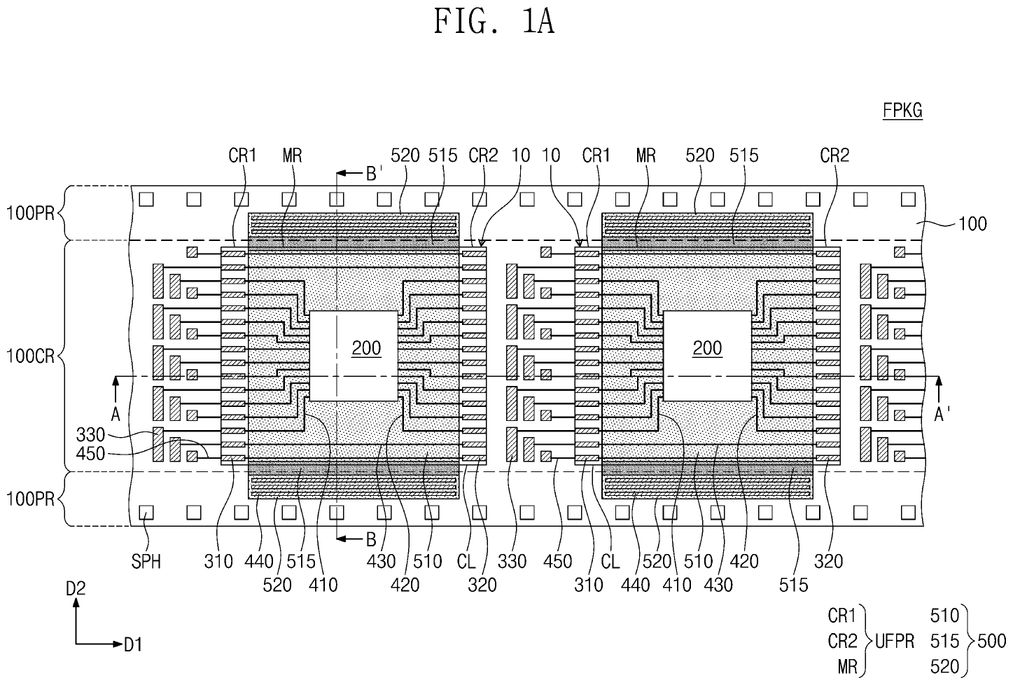

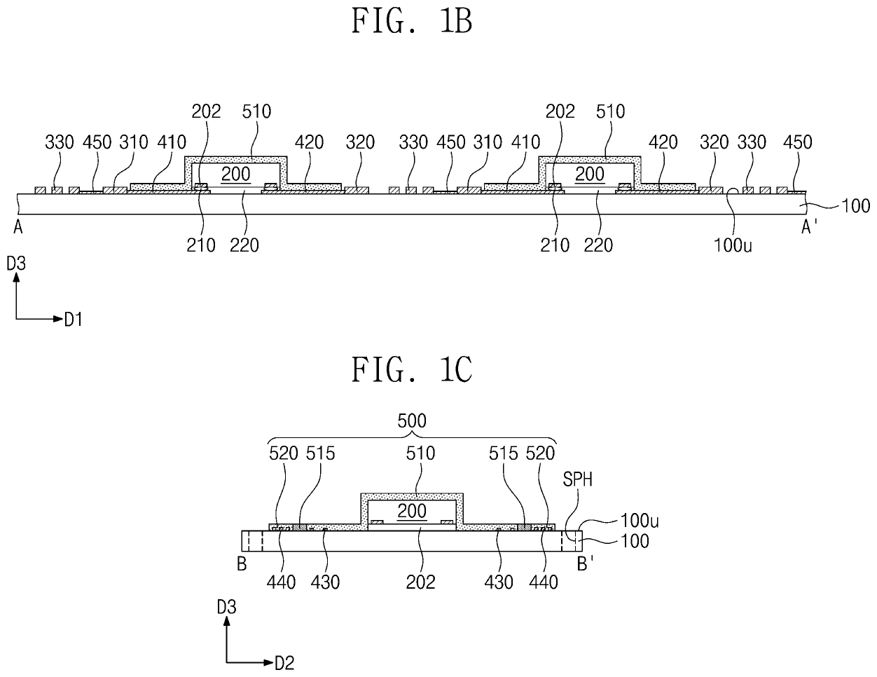

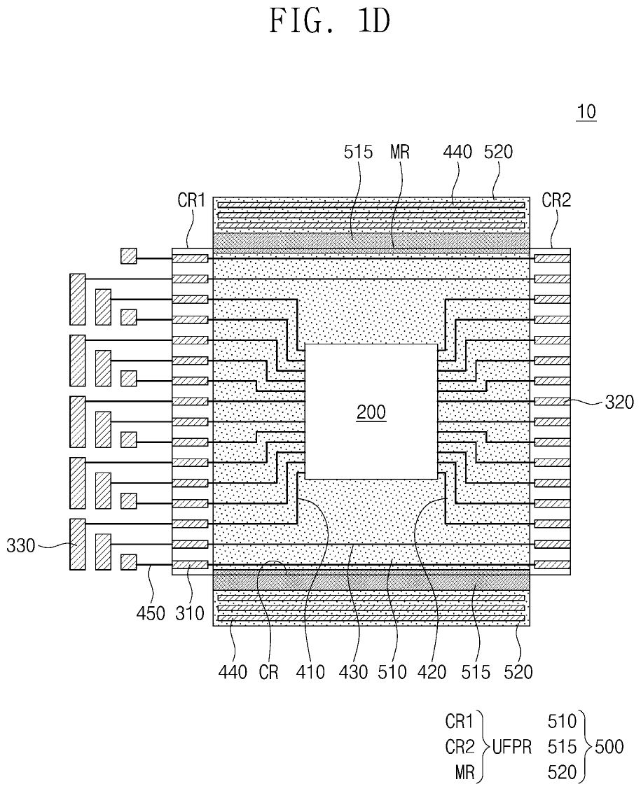

FIG. 1A is a plan view showing a semiconductor package according to some embodiments of the present inventive concepts. FIGS. 1B and 1C are cross-sectional views respectively taken along lines A-A′ and B-B′ of FIG. 1A. FIG. 1D is an enlarged plan view showing a unit film package of FIG. 1A.

Referring to FIGS. 1A to 1D, a film package FPKG may be adopted as a semiconductor package, according to some embodiments of the present inventive concepts. The film package FPKG may include a film substrate 100, at least one semiconductor chip 200, first and second connection pads 310 and 320, and connection lines 410, 420, and 430.

The film substrate 100 may be a base film on which the semiconductor chip 200, the first and second connection pads 310 and 320, and the connection lines 410, 420, and 430 are disposed. The film substrate 100 may extend in a first direction D1. In the following description, the first direction D1 may be defined as a longitudinal length of the film substrate 100 parallel to a mounting surface of the film substrate 100, and a second direction D2 may be a width direction of the film substrate 100 parallel to the mounting surface of the film substrate 100. The film substrate 100 may include a polymeric material, for example, polyimide. The film substrate 100 may be flexible.

The film substrate 100 may have an inner region 100CR and peripheral regions 100PR.

In a plan view, the peripheral regions 100PR may be positioned on opposite ends in the second direction D2 of the film substrate 100, or on an edge of the film substrate 100. The peripheral regions 100PR may extend in the first direction D1. For example, the peripheral regions 100PR may have a linear shape that extends along the edge of the film substrate 100. The peripheral regions 100PR may be an area on which sprocket holes SPH are provided. The sprocket holes SPH may be arranged along the first direction D1 on the peripheral regions 100PR. The sprocket holes SPH may constitute a single row in the first direction D1 on one peripheral region 100PR. The sprocket holes SPH may constitute two, three, or more rows on one peripheral region 100PR. There may be a regular interval in the first direction D1 between the sprocket holes SPH. The sprocket holes SPH may vertically penetrate in a third direction D3 with the film substrate 100. The third direction D3 may be perpendicular to the film substrate 100 and may intersect both of the first direction D1 and the second direction D2. The sprocket holes SPH may be used to wind or move the film substrate 100. For example, pins of a transfer apparatus may be inserted into the sprocket holes SPH, and movement of the pins may force the film substrate 100 to move in the first direction D1.

In a plan view, the inner region 100CR may be positioned in the second direction D2 between the peripheral regions 100PR. For example, the peripheral regions 100PR may be spaced apart in the second direction D2 from each other across the inner region 100CR. The inner region 100CR may have a linear shape that extends in the first direction D1. A width in the second direction D2 of the inner region 100CR may be greater those of the peripheral regions 100PR. The inner region 100CR may be an area on which unit film packages 10 are provided. The unit film packages 10 may be arranged in the first direction D1.

Each of the unit film packages 10 may be provided on an area defined by a cut line CL on the film substrate 100. In the film package FPKG, the cut line CL may be an imaginary line by which unit film package regions UFPR are defined on the film substrate 100. When the unit film packages 10 is to be used, a process may be employed to separate the unit film packages 10 from the film package FPKG, and in this process, the unit film package regions UFPR may be separated along the cut line CL from the film substrate 100. For example, the cut line CL may define an area where the unit film packages 10 are provided in the film package FPKG. In the film package FPKG, an area outside the cut line CL or an area other than the unit film package regions UFPR may be a residual region that is not used as the unit film package 10. The residual region may be used in transferring and protecting the film substrate 100 including the unit film packages 10. The unit film package regions UFPR may overlap the inner region 100CR. For example, the unit film package regions UFPR may be positioned in the inner region 100CR. The unit film packages UFPR may be arranged along the first direction D1. A value of about 8 mm to about 100 mm in the second direction D2 may be given to a difference in width between the unit film package regions UFPR and the film substrate 100. For example, a value of about 4.5 mm to about 50 mm in the second direction D2 may be given to a distance between an end of the unit film package regions UFPR and its adjacent one of opposite ends of the film substrate 100, or between the cut line CL of the unit film package regions UFPR and the opposite ends of the film substrate 100.

The unit film packages 10 may include the unit film package regions UFPR of the film substrate 100 and components on the unit film package regions UFPR. The following description will focus on a single unit film package 10.

One unit film package 10 may be provided on one unit film package region UFPR. The unit film package regions UFPR may each have a mounting region MR and connection regions CR1 and CR2.

The mounting region MR may be positioned on the inner region 100CR. In a plan view, the mounting region MR may be provided between the peripheral regions 100PR. For example, the mounting region MR might not overlap the peripheral regions 100PR. A width in the second direction D2 of the mounting region MR may be less than an interval between the sprocket holes SPH that are adjacent to each other in the second direction D2. For example, the width in the second direction D2 of the mounting region MR may be less than the width in the second direction D2 of the inner region 100CR. The mounting region MR might not overlap the sprocket holes SPH. The mounting region MR may be an area on which the semiconductor chip 200 is provided as discussed below.

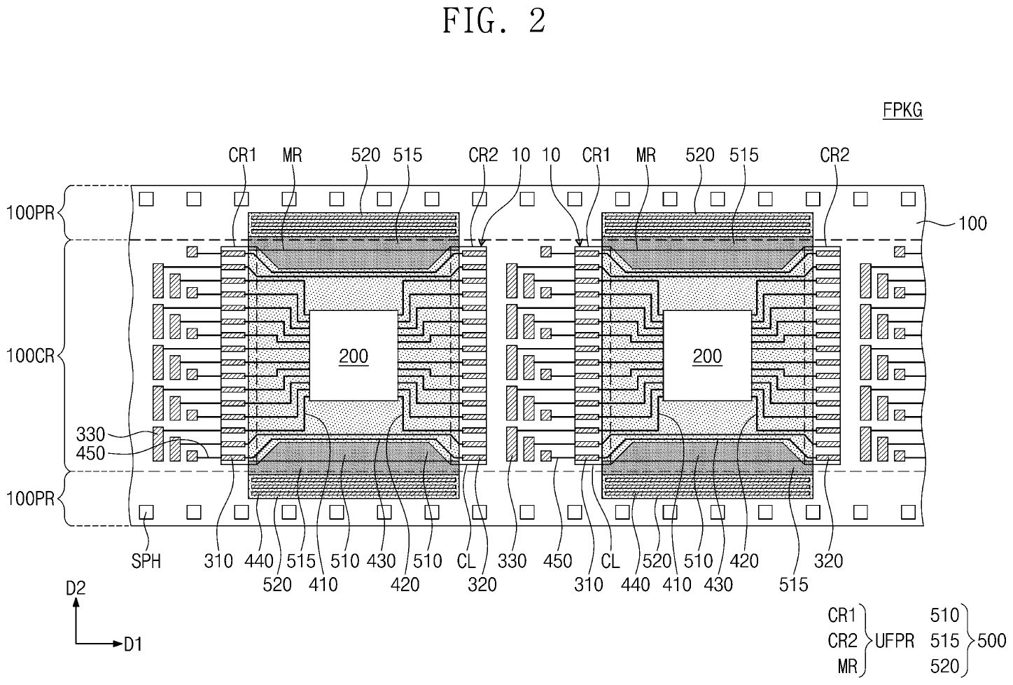

The connection regions CR1 and CR2 may be positioned on opposite sides of the mounting region MR. For example, the first connection region CR1 may be connected to the mounting region MR in a direction opposite to the first direction D1, and the second connection region CR2 may be connected in the first direction D1 to the mounting region MR. A width in the second direction D2 of the mounting region MR may be equal to that of the first connection region CR1 and the second connection region CR2. Therefore, the unit film package regions UFPR may have a tetragonal shape in a plan view. Alternatively, as shown in FIG. 2, the width in the second direction D2 of the mounting region MR may be less than that of the first connection region CR1 and the second connection region CR2. Therefore, the unit film package regions UFPR may have an H shape in a plan view. The following description will focus on the embodiment of FIG. 1A. The first connection region CR1 and the second connection region CR2 may each have a linear shape that extends in the second direction D2. The width in the second direction D2 of the first connection region CR1 and the second connection region CR2 may be less than that of the inner region 100CR.

The semiconductor chip 200 may be provided on a front surface 100u of the film substrate 100. In the following description, the front surface may indicate a surface on which electronic elements are mounted in the film substrate 100, and the film substrate 100 may be provided thereon with wiring lines or pads for mounting and connecting the electronic elements. Alternatively, the film substrate 100 may be provided on its front surface 100u with only the lines or the pads without the electronic elements. There might be no electronic elements provided on a rear surface of the film substrate 100, opposite to the front surface 100u of the film substrate 100. According to some embodiments, the film substrate 100 may be provided on its rear surface with only the wiring lines or the pads, or with the electronic elements with the wiring lines or the pads. The following description will focus on the embodiment of FIGS. 1A to 1D. The semiconductor chip 200 may be provided on the mounting region MR of the unit film package region UFPR. The semiconductor chip 200 may be disposed in a face-down state on the film substrate 100. For example, an active surface of the semiconductor chip 200 may face the film substrate 100. The semiconductor chip 200 may have chip pads 202 provided on its one surface directed toward the film substrate 100.

FIGS. 1A to 1D depict that one semiconductor chip 200 is provided on one mounting region MR, but the present inventive concepts are not necessarily limited thereto. According to some embodiments, a plurality of semiconductor chips 200 may be provided on a single mounting region MR.

The connection lines 410, 420, and 430 may be disposed on the front surface 100u of the film substrate 100. The connection lines 410, 420, and 430 may be line patterns provided on the front surface 100u of the film substrate 100. The connection lines 410, 420, and 430 may be provided on the unit film package region UFPR. For example, the connection lines 410, 420, and 430 may extend from the mounting region MR toward the first connection region CR1 or the second connection region CR2. The connection lines 410, 420, and 430 may include first connection lines 410 and second connection lines 420. The first connection lines 410 may extend along a direction opposite to the first direction D1 from the semiconductor chip 200 toward the first connection region CR1. The first connection lines 410 may be spaced apart in the second direction D2 from each other on one side in a direction opposite to the first direction D1 of the semiconductor chip 200. The second connection lines 420 may extend along the first direction D1 from the semiconductor chip 200 toward the second connection region CR2. The second connection lines 420 may be spaced apart in the second direction D2 from each other on one side in the first direction D1 of the semiconductor chip 200. An interval between the first connection lines 410 on the first connection region CR1 and an interval between the second connection lines 420 on the second connection region CR2 may be less than an interval between the first connection lines 410 below the semiconductor chip 200 and an interval between the second connection lines 420 below the semiconductor chip 200. For example, the interval between the first connection lines 410 may increase in a direction from the semiconductor chip 200 toward the first connection region CR1, and the interval between the second connection lines 420 may increase in a direction from the semiconductor chip 200 toward the second connection region CR2. Differently from that shown, one of the interval between the first connection lines 410 and the interval between the second connection lines 420 may be uniform on the mounting region MR and the connection regions CR1 and CR2.

One or more of the connection lines 410, 420, and 430 might not be connected to the semiconductor chip 200. For example, the connection lines 410, 420, and 430 may include third connection lines 430. The third connection lines 430 may be positioned in the second direction D2 or its opposite direction from the semiconductor chip 200. For example, the third connection lines 430 may run from one side of the semiconductor chip 200 across the semiconductor chip 200 to another side of the semiconductor chip 200, thereby connecting the first connection region CR1 to the second connecting region CR2. The third connection lines 430 may be horizontally spaced apart from the first connection lines 410 and the second connection lines 420. The third connection lines 430 may directly connect the first connection pads 310 and the second connection pads 320 to each other which, will be discussed below.

On the film substrate 100, the semiconductor chip 200 may be mounted on the first connection lines 410 and the second connection lines 420. For example, portions of the first connection lines 410 and portions of the second connection lines 420 may overlap the semiconductor chip 200. As shown in FIGS. 1B and 1C, the portions of the first connection lines 410 and the portions of the second connection lines 420 may extend below the semiconductor chip 200. For example, the portions of the first connection lines 410 and the portions of the second connection lines 420 may vertically overlap the chip pads 202. Chip terminals 210 may be provided between the chip pads 202 and the portions of the first connection lines 410 and between the chip pads 202 and the portions of the second connection lines 420. The semiconductor chip 200 may be electrically connected through the chip terminals 210 to the first connection lines 410 and the second connection lines 420. The chip terminals 210 may include solders, pillars, and/or bumps. The chip terminals 210 may include metal.

An underfill layer 220 may be formed in a gap between the film substrate 100 and the semiconductor chip 200, filling the gap. The underfill layer 220 may encapsulate the chip terminals 210. The underfill layer 220 may include a dielectric polymer, such as an epoxy-based polymer.

The connection pads 310 and 320 may be provided on the front surface 100u of the film substrate 100. The connection pads 310 and 320 may be provided on the first connection region CR1 and the second connection region CR2. The connection pads 310 and 320 may include first connection pads 310 provided on the first connection region CR1 and second connection pads 320 provided on the second connection region CR2. The first connection pads 310 may be arranged in the second direction D2 on the first connection region CR1. For example, the first connection pads 310 may be arranged along an end in a direction opposite to the first direction D1 of the first connection region CR1. FIG. 1A depicts that the first connection pads 310 are in contact with the end in a direction opposite to the first direction D1 of the first connection region CR1, but the present inventive concepts are not necessarily limited thereto. The first connection pads 310 may be spaced apart from the end in a direction opposite to the first direction D1 of the first connection region CR1. The second connection pads 320 may be arranged in the second direction D2 on the second connection region CR2. For example, the second connection pads 320 may be arranged along an end in the first direction D1 of the second connection region CR2. FIG. 1A depicts that the second connection pads 320 are in contact with the end in the first direction D1 of the second connection region CR2, but the present inventive concepts are not necessarily limited thereto. The second connection pads 320 may be spaced apart from the end in the first direction D1 of the second connection region CR2. When the unit film packages 10 are separated from the film substrate 100, the first connection pads 310 and the second connection pads 320 may be pads for electrically connecting the unit film packages 10 to an external apparatus.

The first connection pads 310 and the second connection pads 320 may be electrically connected to the semiconductor chip 200. The first connection pads 310 may be connected through the first connection lines 410 to the semiconductor chip 200, and the second connection pads 320 may be connected through the second connection lines 420 to the semiconductor chip 200. Some of the first connection pads 310 may be directly connected through the third connection lines 430 to some of the second connection pads 320. As shown in FIG. 1A, the connection lines 410, 420, and 430 may be curved. The present inventive concepts, however, are not necessarily limited thereto, and the shapes of the connection lines 410, 420, and 430 may be variously changed depending on an arrangement of the first connection pads 310 and the second connection pads 320, a size of the semiconductor chip 200, and an arrangement of the chip pads 202 of the semiconductor chip 200.

As discussed above, the unit film packages 10 may be provided on the film substrate 100.

First dummy lines 440 may be disposed on the front surface 100u of the film substrate 100. The first dummy lines 440 may be dummy patterns provided on the front surface 100u of the film substrate 100. The first dummy lines 440 may be provided in the second direction D2 or its opposite direction from the unit film package region UFPR of one unit film package 10. For example, the first dummy lines 440 may be disposed on the peripheral regions 100PR of the film substrate 100. The first dummy lines 440 may be disposed in the second direction D2 between the unit film package regions UFPR and the sprocket holes SPH. The first dummy lines 440 may each have a linear shape that extends in the first direction D1. The first dummy lines 440 may be arranged in the second direction D2. The first dummy lines 440 may be separately provided on one side of each of the unit film package regions UFPR, and the first dummy lines 440 adjacent to one unit film package region UFPR might not be connected to other first dummy lines 440 adjacent to another unit film package region UFPR. For example, the first dummy lines 440 may be disposed on one side of the mounting region MR of the unit film package region UFPR, and might not be disposed on one sides of the connection regions CR1 and CR2. A length in the first direction D1 of the first dummy lines 440 may be less than that of the mounting region MR. For example, the first dummy lines 440 may be positioned in the first direction D1 between the first connection region CR1 and the second connection region CR2.

A region where lines or pads are not provided on the film substrate 100 may be deformed more easily than a region where lines or pads are provided. In a semiconductor package, according to some embodiments of the present inventive concepts, as the first dummy lines 440 are disposed on the peripheral regions 100PR on which neither the connection lines 410, 420, and 430 nor the pads 310 and 320 are provided. Therefore, the film package FPKG may be prevented from being deformed in a width direction (e.g., the second direction D2), not a longitudinal direction (e.g., the first direction D1), and the film package FPKG and the unit film package 10 may increase in structural stability.

The film substrate 100 may have test pads 330 provided on the front surface 100u of the film substrate 100. For example, the test pads 330 may be disposed on the film substrate 100 in a direction opposite to the first direction D1 from the first connection pads 310. For example, the test pads 330 may be spaced apart in a direction opposite to the first direction D1 from the unit film package regions UFPR or the first connection region CR1 of each of the unit film package regions UFPR. When the unit film package 10 is provided in plural, the test pads 330 may be positioned in the second direction D2 between the unit film package regions UFPR. The test pads 330 may be arranged in the second direction D2. FIG. 1A depicts that the test pads 330 are arranged in three rows, but the present inventive concepts are not necessarily limited thereto. The test pads 330 may be arranged in various ways as needed. The test pads 330 may be arranged on one side in a direction opposite to the first direction D1 of the first connection pads 310, and each of the test pads 330 may be positioned in a direction opposite to the first direction D1 from one of the first connection pads 310. The test pads 330 may be pads provided on the film substrate 100 for inspecting failure of a semiconductor package in fabricating the semiconductor package.

The test pads 330 may be connected to the semiconductor chip 200. For example, the film substrate 100 may be provided on its front surface 100u with test connection lines 450 that connect the semiconductor chip 200 to the test pads 330. Each of the test connection lines 450 may connect one of the test pads 330 to one of the first connection pads 310. The test connection lines 450 may extend in a direction opposite to the first direction D1 from the first connection pads 310 across the cut line CL toward the test pads 330. The test connection lines 450 may be lead lines provided on the front surface 100u of the film substrate 100.

Protection layers 500 may be provided on the film substrate 100. The protection layers 500 may be attached to the film substrate 100 to cover the unit film packages 10. Each of the protection layers 500 may encapsulate the semiconductor chip 200, while being in physical contact with top and lateral surfaces of the semiconductor chip 200 of the unit film packages 10. The protection layers 500 may cover the semiconductor chips 200. The protection layers 500 may at least partially cover the first connection lines 410, the second connection lines 420, and the third connection lines 430, and may expose the first connection pads 310 and the second connection pads 320. The protection layers 500 may include a solder resist material. Each of the protection layers 500 may include a first solder resist layer 510, second solder resist layers 520, and first extension parts 515. In FIGS. 1A to 1D, for convenience of description, the first solder resist layer 510, the second solder resist layers 520, and the first extension parts 515 are illustrated as separate components from each other, but the present inventive concepts are not necessarily limited thereto. The first solder resist layer 510, the second solder resist layers 520, and the first extension parts 515 may be formed of the same material, and may be connected portions of the protection layer 500. For example, first solder resist layer 510, the second solder resist layers 520, and the first extension parts 515 may correspond to one solder resist layer. The following description will focus on one unit film package 10 for explaining a configuration of the protection layers 500.

On the mounting region MR, the first solder resist layer 510 may cover at least a portion of the unit film package 10. For example, on the film substrate 100, the first solder resist layer 510 may cover the semiconductor chip 200, the first connection lines 410, the second connection lines 420, and the third connection lines 430. The first solder resist layer 510 may have lateral parts in the first direction D1 that are disposed adjacent to and spaced apart from the first connection pads 310 and the second connection pads 320. The first solder resist layer 510 may have lateral parts in the second direction D2 that are disposed in the second direction D2 or its opposite direction on one side of the semiconductor chip 200 and are adjacent to or in contact with the cut line CL. For example, on the unit film package region UFPR, the first solder resist layer 510 may cover the mounting region MR and expose the connection regions CR1 and CR2. The protection layer 500 may include a portion provided on the mounting region MR so as to cover the unit film package 10, and the first solder resist layer 510 may be the portion of the protection layer 500. The first solder resist layer 510 may expose the first connection pads 310.

The second solder resist layers 520 may each be disposed in the second direction D2 or its opposite direction from the first solder resist layer 510. The second solder resist layers 520 may correspondingly cover the first dummy lines 440 on the peripheral regions 100PR. For example, on the film substrate 100, the second solder resist layers 520 may completely cover the first dummy lines 440. The second solder resist layers 520 may be spaced apart from the first solder resist layer 510. For example, the second solder resist layers 520 may be disposed on corresponding peripheral regions 100PR, and might not extend onto the inner region 100CR. The protection layer 500 may include portions provided on the peripheral regions 100PR so as to cover the first dummy lines 440, and the second solder resist layers 520 may be the portions of the protection layer 500. A length in the first direction D1 of each of the second solder resist layers 520 may be the same as that of the first solder resist layer 510.

The first extension parts 515 may be positioned between the first solder resist layer 510 and the second solder resist layers 520. For example, each of the first extension parts 515 may connect one of the second solder resist layers 520 to the first solder resist layer 510. The first extension parts 515 may extend from the peripheral regions 100PR toward the inner region 100CR, and may run across the cut line CL of the unit film package region UFPR to extend onto the mounting region MR. The first extension parts 515 may be connected to the second solder resist layers 520 on the peripheral regions 100PR and to the first solder resist layer 510 on the mounting region MR. For example, the protection layer 500 may include portions provided on the cut line CL so as to connect the first solder resist layer 510 to the second solder resist layers 520, and the first extension parts 515 may be the portions of the protection layer 500. The first extension parts 515 may cover at least a portion of the cut line CL positioned in the first direction D1 or its opposite direction of the unit film package region UFPR, and for example, may cover the film substrate 100 on which the cut line CL is provided on opposite sides in the second direction D2 of the unit film package 10. On the cut line CL positioned in the first direction D1 or its opposite direction of the unit film package region UFPR, the first extension parts 515 may be in contact with the film substrate 100.

Based on shapes of the first solder resist layer 510, the second solder resist layers 520, and the first extension parts 515, the protection layer 500 may cover the first dummy lines 440 on the peripheral regions 100PR, and may run across the cut line CL and extend onto the mounting region MR to cover the unit film package 10. The protection layer 500 may expose the first connection pads 310 and the second connection pads 320.

A region on a cut line where no protection layer is provided may be deformed more easily than a region where a protection layer is provided. In a semiconductor package, according to some embodiments of the present inventive concepts, the protection layer 500 may be disposed on the cut line CL in addition to the unit film package 10 and the first dummy lines 440, and thus the film substrate 100 might not be easily deformed around the cut line CL. Therefore, the film package FPKG may be prevented from being deformed in a width direction (e.g., the second direction D2), not a longitudinal direction (e.g., the first direction D1), and the film package FPKG and the unit film package 10 may increase in structural stability.

In the embodiments that follow, a detailed description of technical features repetitive to those discussed above with reference to FIGS. 1A to 1D will be omitted, and a difference thereof will be discussed in detail. The same reference numerals will be allocated to the components the same as or similar to those of the semiconductor package discussed above according to some embodiments of the present inventive concepts.

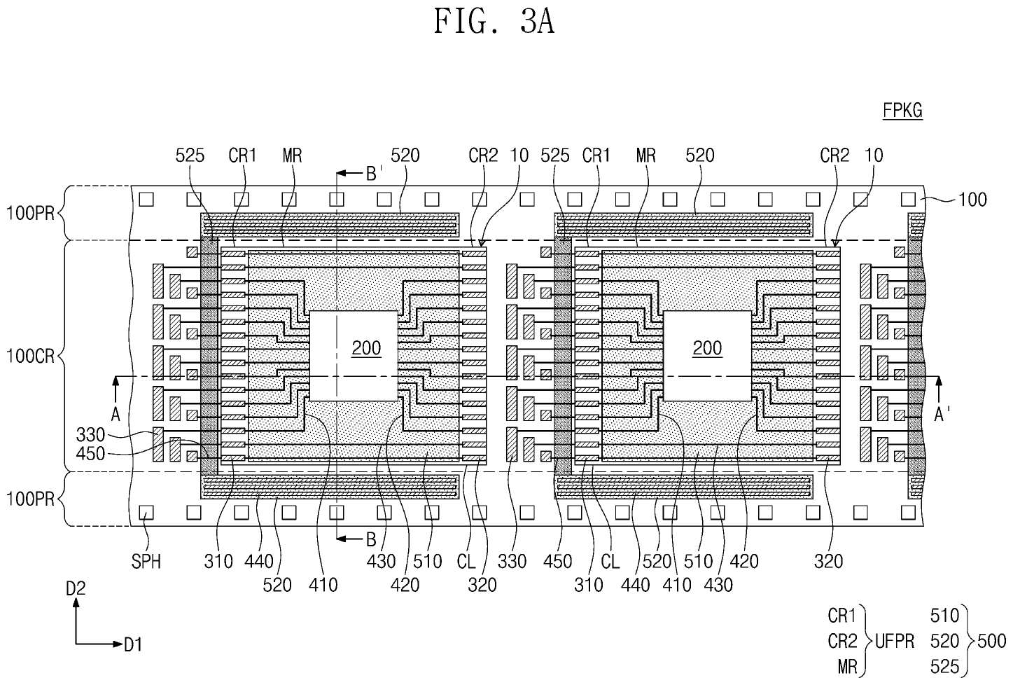

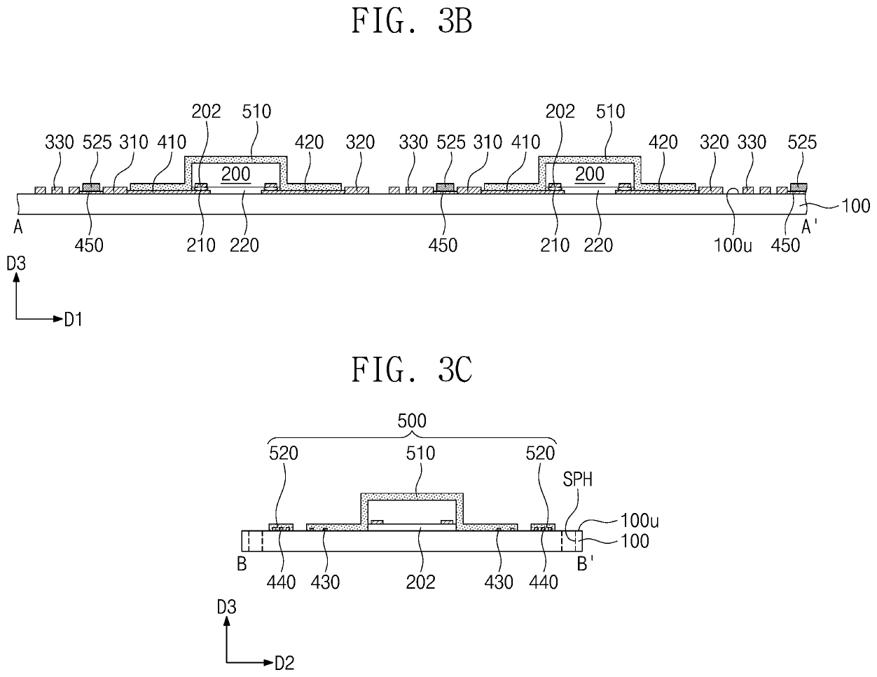

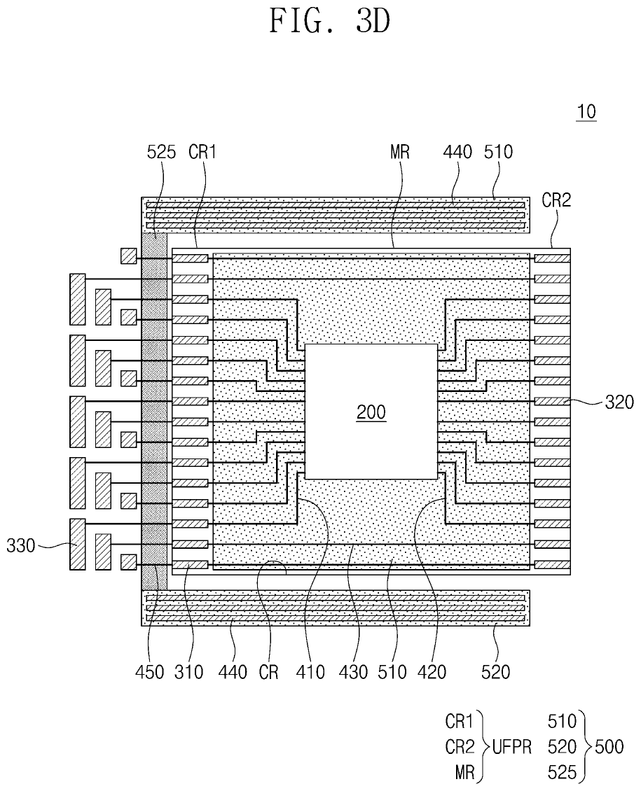

FIG. 3A is a plan view showing a semiconductor package according to some embodiments of the present inventive concepts. FIGS. 3B and 3C are cross-sectional views respectively taken along lines A-A′ and B-B′ of FIG. 3A. FIG. 3D is an enlarged plan view showing a unit film package of FIG. 3A.

Referring to FIGS. 3A to 3D, differently from the embodiment of FIGS. 1A to 1D, each of the protection layers 500 may include a first solder resist layer 510, second solder resist layers 520, and a second extension part 525, but might not include the first extension part 515. In FIGS. 3A to 3D, for convenience of description, the first solder resist layer 510, the second solder resist layers 520, and the second extension part 525 are illustrated as separate components from each other, but the present inventive concepts are not necessarily limited thereto. The first solder resist layer 510, the second solder resist layers 520, and the second extension part 525 may be formed of the same material, and may be connected portions of the protection layer 500. The second solder resist layers 520 and the second extension part 525 may correspond to one solder resist layer. The following description will focus on one unit film package 10 for explaining a configuration of the protection layers 500.

The second solder resist layers 520 may each be disposed in the second direction D2 or its opposite direction from the first solder resist layer 510. A length in the first direction D1 of each of the second solder resist layers 520 may be greater than that of the first solder resist layer 510. For example, when viewed in the first direction D1, one end of the second solder resist layers 520 may be positioned between the unit film package region UFPR and the test pads 330.

The second extension part 525 may be positioned in a direction opposite to the first direction D1 from the first solder resist layer 510. For example, the second extension part 525 may be positioned between the unit film package region UFPR and the test pads 330. In this configuration, the second extension part 525 may be spaced apart from the cut line CL positioned in a direction opposite to the first direction D1 of the unit film package region UFPR. Thus, the second extension part 525 may be spaced apart in a direction opposite to the first direction D1 from the first connection pads 310 of the unit film package 10. The first connection pads 310 may be positioned between the first solder resist layer 510 and the second extension part 525, and might not be covered with the protection layer 500. The second extension part 525 may be spaced apart from the test pads 330. For example, the test pads 330 might not be covered with the protection layer 500. The second extension part 525 may cover the test connection lines 450. The second extension part 525 may extend in the second direction D2 and be connected to the second solder resist layers 520. The second extension part 525 may be portions of the protection layer 500 that are provided for connection of the second solder resist layers 520. In a plan view, the second solder resist layers 520 and the second extension part 525 may each have a II (or bracket) shape that surrounds the first solder resist layer 510 or the unit film package region UFPR.

In a semiconductor package, according to some embodiments of the present inventive concepts, as the second solder resist layers 520 and the second extension part 525 surround the unit film package region UFPR, the film substrate 100 might not be easily deformed in the vicinity of the unit film package region UFPR and the unit film package 10. Therefore, the film package FPKG may be prevented from being deformed, and the film package FPKG and the unit film package 10 may increase in structural stability.

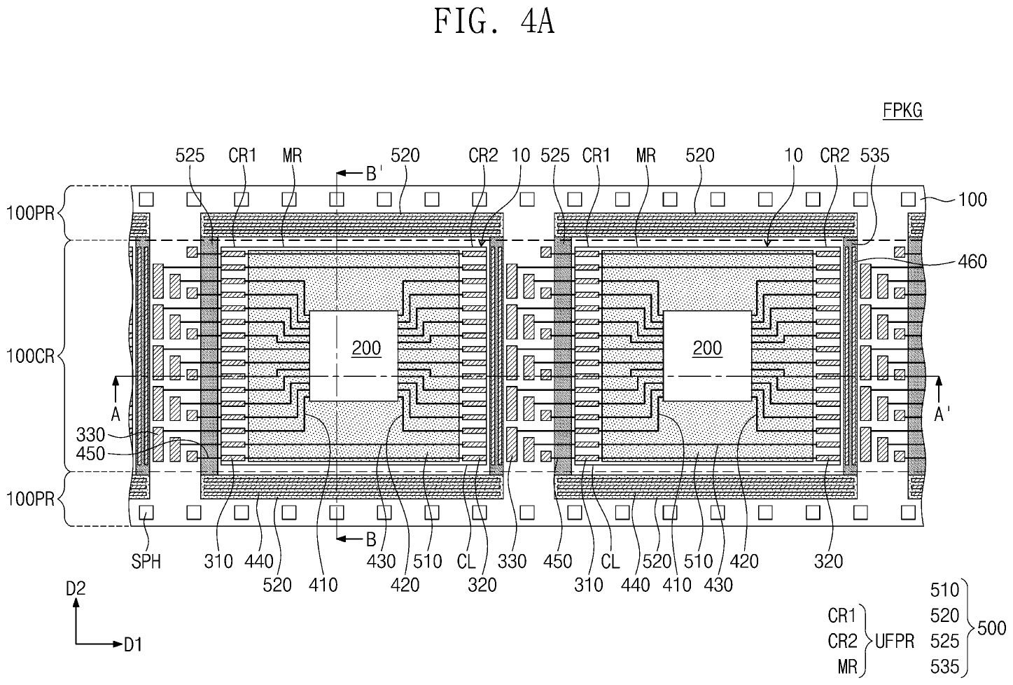

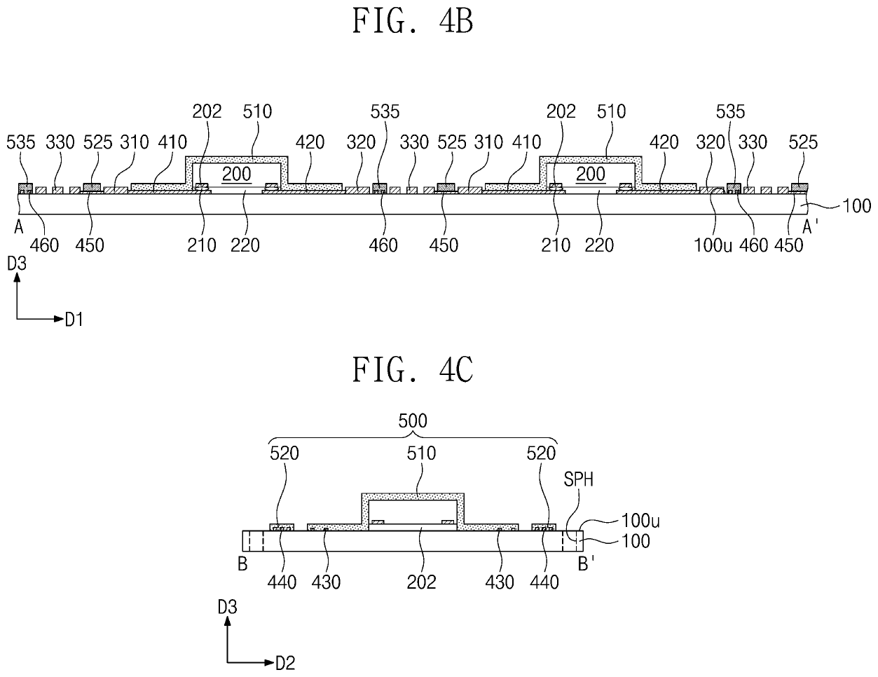

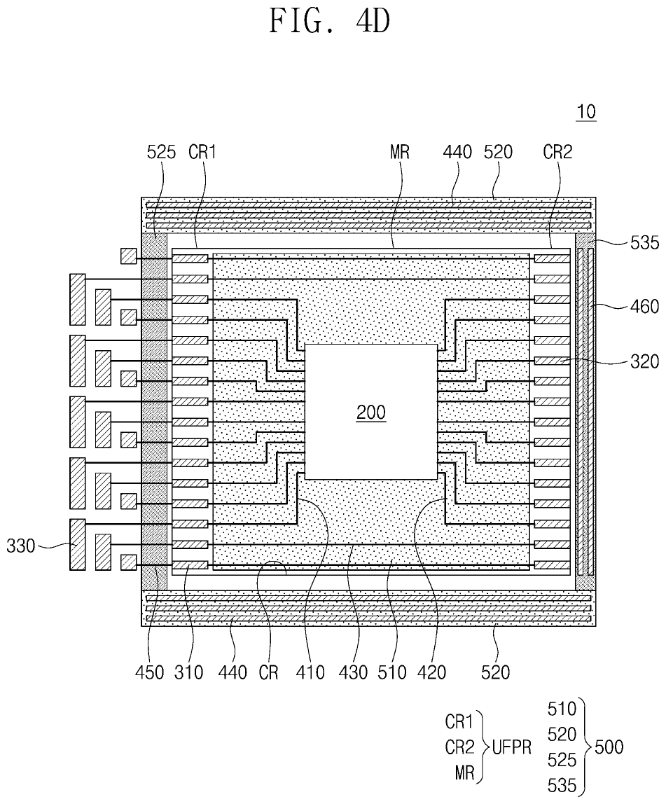

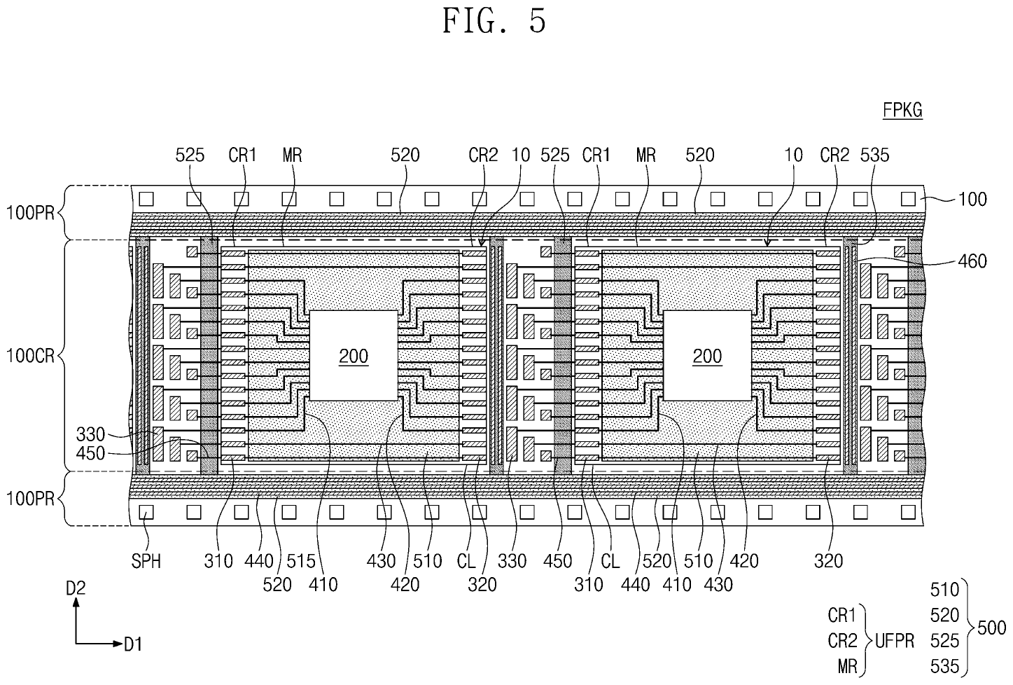

FIG. 4A is a plan view showing a semiconductor package according to some embodiments of the present inventive concepts. FIGS. 4B and 4C are cross-sectional views respectively taken along lines A-A′ and B-B′ of FIG. 4A. FIG. 4D is an enlarged plan view showing a unit film package of FIG. 4A. FIG. 5 is a plan view showing a semiconductor package according to some embodiments of the present inventive concepts.

Referring to FIGS. 4A to 4D, differently from the embodiment of FIGS. 3A to 3D, the film package FPKG may further include second dummy lines 460, and the protection layers 500 of the film package FPKG may each include a first solder resist layer 510, second solder resist layers 520, a second extension part 525, and a third extension part 535. In FIGS. 4A to 4D, for convenience of description, the first solder resist layer 510, the second solder resist layers 520, the second extension part 525, and the third extension part 535 are illustrated as separate components from each other, but the present inventive concepts are not necessarily limited thereto. The first solder resist layer 510, the second solder resist layers 520, the second extension part 525, and the third extension part 535 may be formed of the same material, and may be connected portions of the protection layer 500. The first solder resist layer 510, the second solder resist layers 520, the second extension part 525, and the third extension part 535 may correspond to one solder resist layer. The following description will focus on one unit film package 10 for explaining a configuration of the second dummy lines 460 and a configuration of the protection layers 500.

The first dummy lines 440 may be disposed on the front surface 100u of the film substrate 100. The first dummy lines 440 may be separately provided on one side of each of the unit film package regions UFPR. A length in the first direction D1 of each of the first dummy lines 440 may be greater than that of the unit film package region UFPR. For example, when viewed in the first direction D1, the unit film package regions UFPR may be positioned between opposite ends of the first dummy lines 440.

FIGS. 4A to 4D depict that the first dummy lines 440 are separately provided on one side of the unit film package regions UFPR, but alternatively, the unit film package regions UFPR may share the same first dummy lines 440. As shown in FIG. 5, the first dummy lines 440 may extend in the first direction D1 on the peripheral regions 100PR of the film substrate 100, and a plurality of unit film package regions UFPR may be positioned on the inner region 100CR between the first dummy lines 440.

The second dummy lines 460 may be disposed on the front surface 100u of the film substrate 100. The second dummy lines 460 may be dummy patterns provided on the front surface 100u of the film substrate 100. The second dummy lines 460 may be provided in the first direction D1 from the unit film package region UFPR of one unit film package 10. For example, the second dummy lines 460 may be disposed on the inner region 100CR of the film substrate 100. The second dummy lines 460 may be spaced apart from the cut line CL positioned in a direction opposite to the first direction D1 of the unit film package region UFPR. For example, the second dummy lines 460 may be spaced apart in the first direction D1 from the second connection pads 320 of the unit film package 10. The second dummy lines 460 may be disposed between the first dummy lines 440 positioned in the second direction D2 form the unit film package region UFPR and the first dummy lines 440 positioned in a direction opposite to the second direction D2 from the unit film package region UFPR. The second dummy lines 460 may each have a linear shape that extends in the second direction D2. The second dummy lines 460 may be arranged in the first direction D1. The second dummy lines 460 may be separately provided on one side of each of the unit film package regions UFPR.

A region where lines or pads are not provided on the film substrate 100 may be deformed more easily than a region where lines or pads are provided. In a semiconductor package, according to some embodiments of the present inventive concepts, as the second dummy lines 460 extending in the second direction D2 are disposed on one side of the unit film package regions UFPR, the film package FPKG may be prevented from being deformed in a width direction (e.g., the second direction D2), not a longitudinal direction (e.g., the first direction D1), and the film package FPKG and the unit film package 10 may increase in structural stability.

The second solder resist layers 520 may each be disposed in the second direction D2 or its opposite direction from the first solder resist layer 510. A length in the first direction D1 of each of the second solder resist layers 520 may be greater than that of the first solder resist layer 510. For example, when viewed in the first direction D1, the unit film package regions UFPR may be positioned between opposite ends of the second solder resist layers 520.

As shown in the embodiment of FIG. 5, when the unit film package regions UFPR share the same first dummy lines 440, the second solder resist layers 520 may cover the first dummy lines 440, while extending in the first direction D1 on the peripheral regions 100PR of the film substrate 100. A plurality of unit film package regions UFPR may be positioned on the inner region 100CR between the second solder resist layers 520.

The third extension part 535 may be positioned in the first direction D1 from the first solder resist layer 510. In this configuration, the third extension part 535 may be spaced apart from the cut line CL positioned in the first direction D1 of the unit film package region UFPR. For example, the third extension part 535 may be spaced apart in the first direction D1 from the second connection pads 320 of the unit film package 10. The second connection pads 320 may be positioned between the first solder resist layer 510 and the third extension part 535, and might not be covered with the protection layer 500. The third extension part 535 may cover the second dummy lines 460. The third extension part 535 may extend in the second direction D2 and be connected to the second solder resist layers 520. The third extension part 535 may be portions of the protection layer 500 that are provided for connection of the second solder resist layers 520. In a plan view, the second solder resist layers 520, the second extension part 525, and the third extension part 535 may each have a tetragonal loop shape that surrounds the first solder resist layer 510 or the unit film package region UFPR.

In a semiconductor package, according to some embodiments of the present inventive concepts, as the second solder resist layers 520, the second extension part 525, and the third extension part 535 completely surround the unit film package region UFPR, the film substrate 100 might not be easily deformed in the vicinity of the unit film package region UFPR and the unit film package 10. Therefore, the film package FPKG may be prevented from being deformed, and the film package FPKG and the unit film package 10 may increase in structural stability.

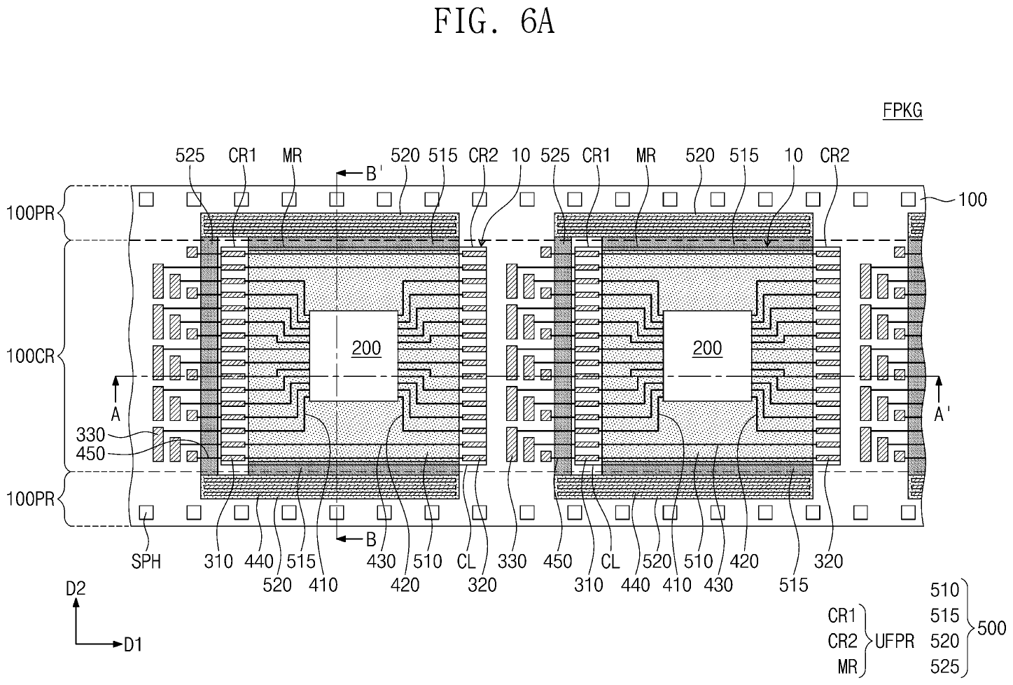

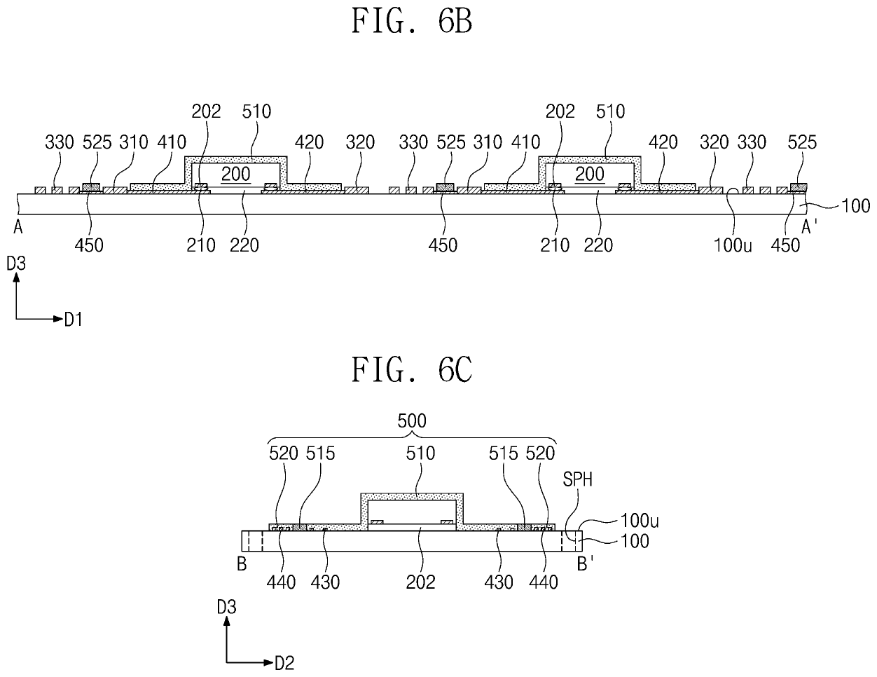

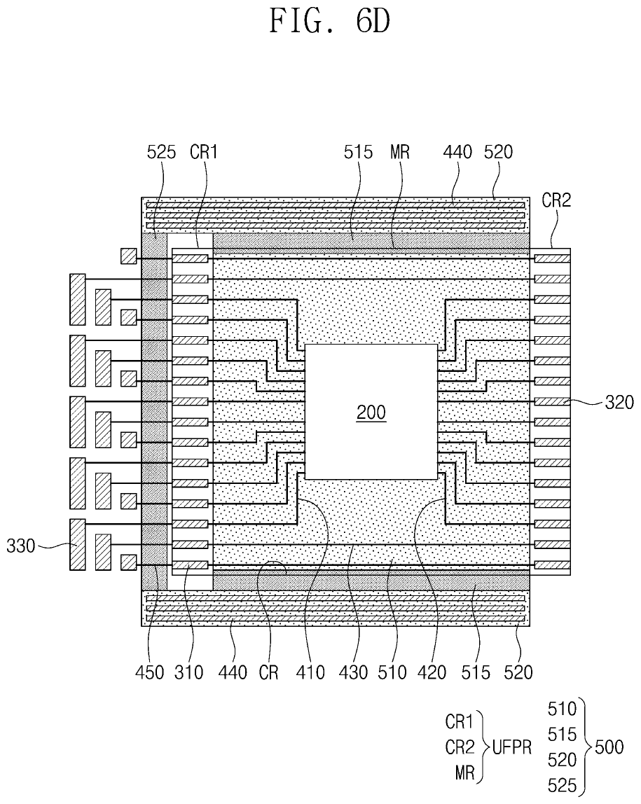

FIG. 6A is a plan view showing a semiconductor package according to some embodiments of the present inventive concepts. FIGS. 6B and 6C are cross-sectional views respectively taken along lines A-A′ and B-B′ of FIG. 6A. FIG. 6D is an enlarged plan view showing a unit film package of FIG. 6A.

Referring to FIGS. 6A to 6D, differently from the embodiment of FIGS. 1A to 1D, each of the protection layers 500 of the film package FPKG may further include a second extension part 525. For example, each of the protection layers 50 may include a first solder resist layer 510, second solder resist layers 520, first extension parts 515, and a second extension part 525. In FIGS. 6A to 6D, for convenience of description, the first solder resist layer 510, the second solder resist layers 520, the first extension parts 515, and the second extension part 525 are illustrated as separate components from each other, but the present inventive concepts are not necessarily limited thereto. The first solder resist layer 510, the second solder resist layers 520, the first extension parts 515, and the second extension part 525 may be formed of the same material, and may be connected portions of the protection layer 500. For example, the first solder resist layer 510, the second solder resist layers 520, the first extension parts 515, and the second extension part 525 may correspond to one solder resist layer. The following description will focus on one unit film package 10 for explaining a configuration of the protection layers 500.

The second solder resist layers 520 may each be disposed in the second direction D2 or its opposite direction from the first solder resist layer 510. A length in the first direction D1 of each of the second solder resist layers 520 may be greater than that of the first solder resist layer 510. For example, when viewed in the first direction D1, one end of the second solder resist layers 520 may be positioned between the unit film package region UFPR and the test pads 330.

The first extension parts 515 may be positioned between the first solder resist layer 510 and the second solder resist layers 520. The first extension parts 515 may extend from the peripheral regions 100PR toward the inner region 100CR, and may run across the cut line CL to extend onto the mounting region MR. The protection layer 500 may include portions provided on the cut line CL so as to connect the first solder resist layer 510 to the second solder resist layers 520, and the first extension parts 515 may be the portions of the protection layer 500.

The second extension part 525 may be positioned in a direction opposite to the first direction D1 from the first solder resist layer 510. For example, the second extension part 525 may be positioned between the unit film package region UFPR and the test pads 330. The second extension part 525 may extend in the second direction D2 and be connected to the second solder resist layers 520. The second extension part 525 may be portions of the protection layer 500 that are provided for connection of the second solder resist layers 520.

Based on shapes of the first solder resist layer 510, the second solder resist layers 520, the first extension parts 515, and the second extension part 525, the protection layer 500 may have a planar shape that exposes the first connection pads 310 and covers the unit film package 10, the first dummy lines 440, and the test connection lines 450.

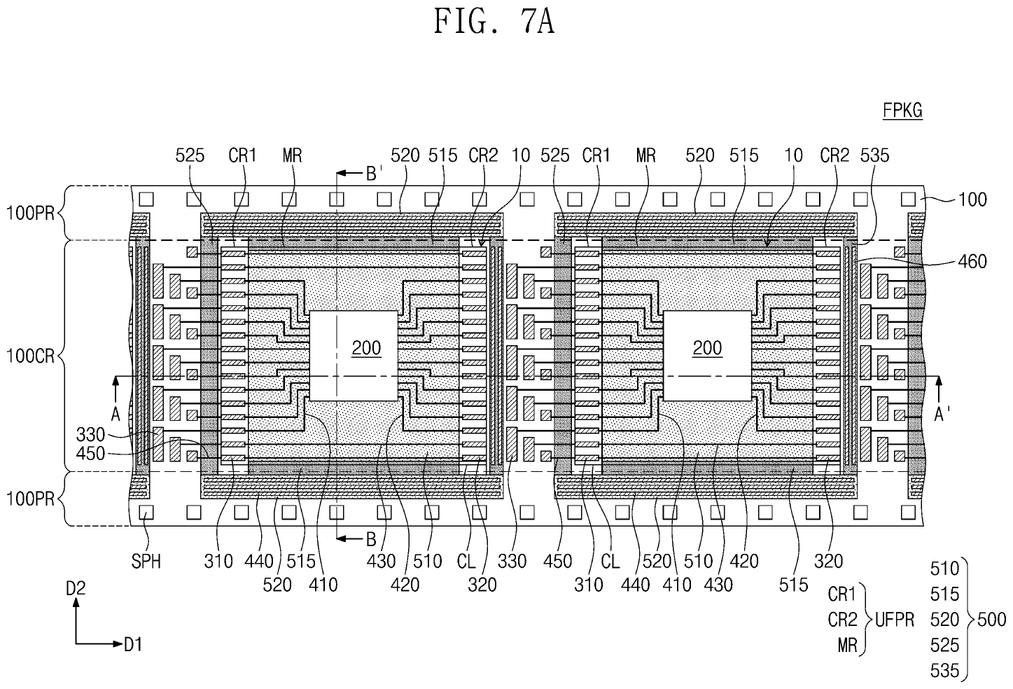

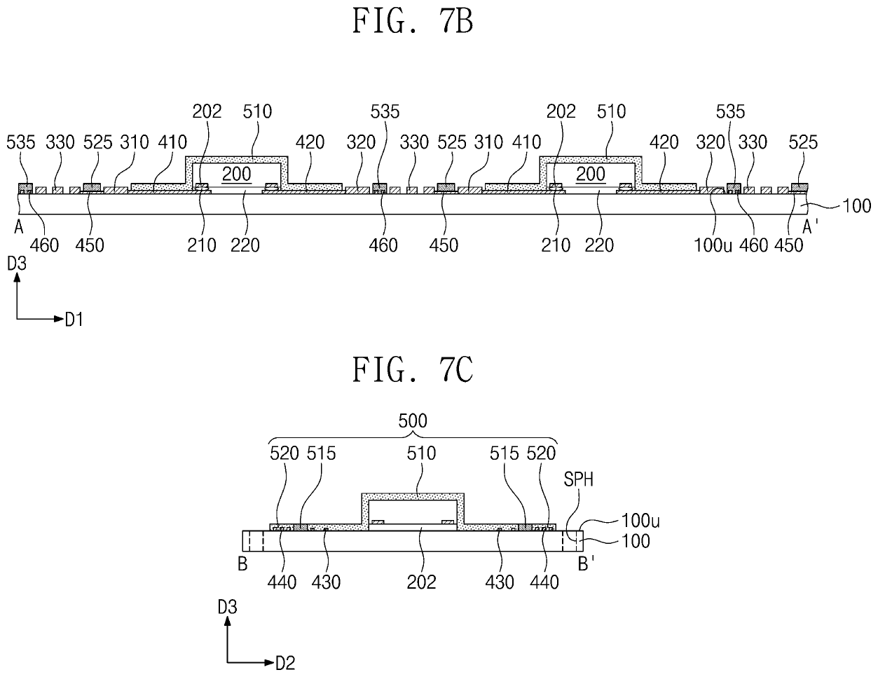

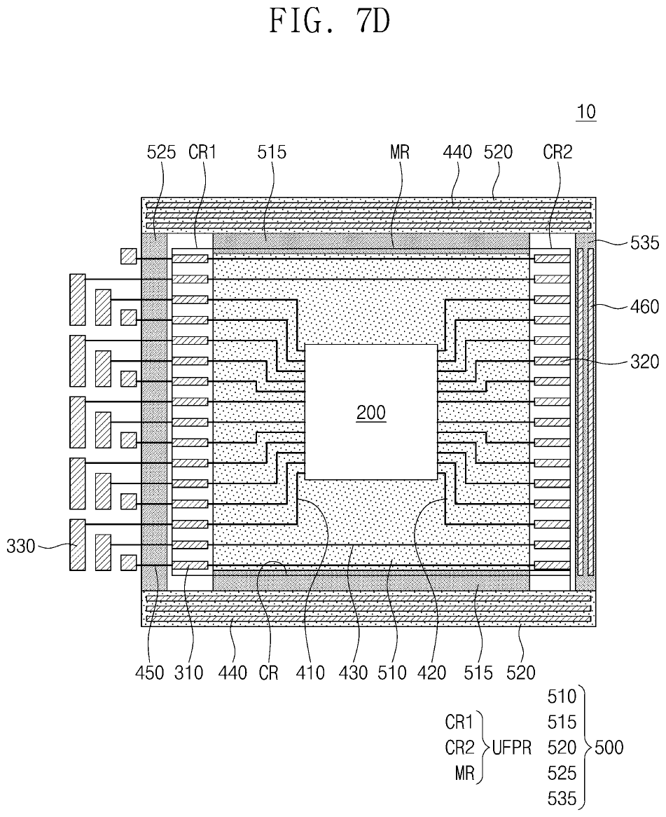

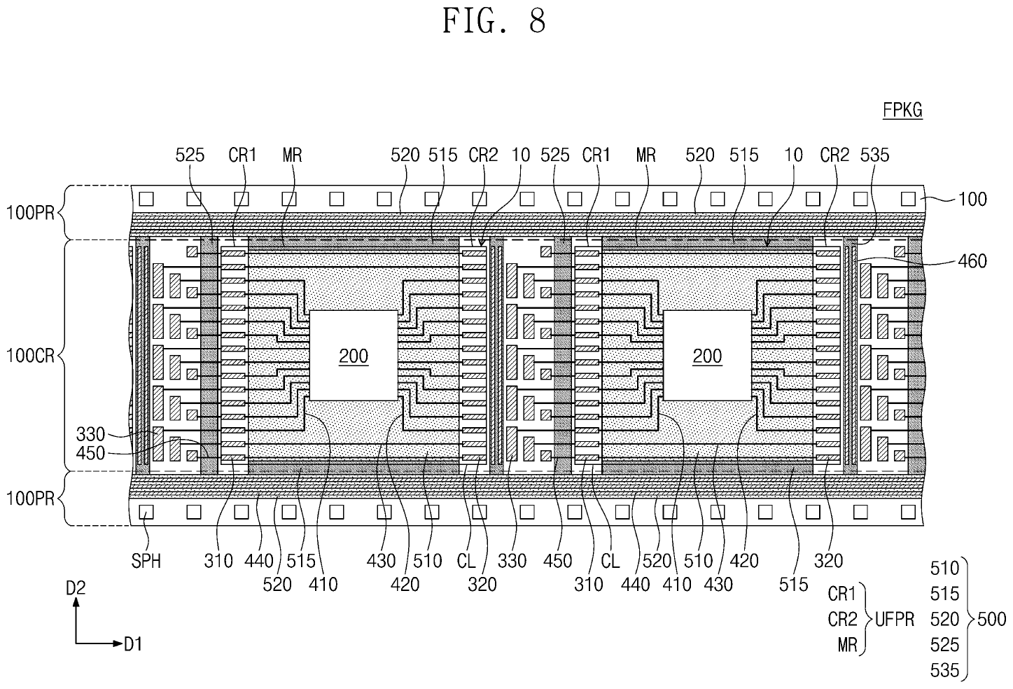

FIG. 7A is a plan view showing a semiconductor package according to some embodiments of the present inventive concepts. FIGS. 7B and 7C are cross-sectional views respectively taken along lines A-A′ and B-B′ of FIG. 7A. FIG. 7D is an enlarged plan view showing a unit film package of FIG. 7A. FIG. 8 is a plan view showing a semiconductor package according to some embodiments of the present inventive concepts.

Referring to FIGS. 7A to 7D, differently from the embodiment of FIGS. 1A to 1D, the film package FPKG may further include second dummy lines 460, and each of the protection layers 500 of the film package FPKG may further include a second extension part 525 and a third extension part 535. For example, each of the protection layers 500 may include a first solder resist layer 510, second solder resist layers 520, first extension parts 515, a second extension part 525, and a third extension part 535. In FIGS. 7A to 7D, for convenience of description, the first solder resist layer 510, the second solder resist layers 520, the first extension parts 515, the second extension part 525, and the third extension part 535 are illustrated as separate components from each other, but the present inventive concepts are not necessarily limited thereto. The first solder resist layer 510, the second solder resist layers 520, the first extension part 515, the second extension part 525, and the third extension part 535 may be formed of the same material, and may be connected portions of the protection layer 500. For example, the first solder resist layer 510, the second solder resist layers 520, the first extension part 515, the second extension part 525, and the third extension part 535 may correspond to one solder resist layer. The following description will focus on one unit film package 10 for explaining a configuration of the protection layers 500.

The first dummy lines 440 may be disposed on the front surface 100u of the film substrate 100. The first dummy lines 440 may be separately provided on one side of each of the unit film package regions UFPR. When viewed in the first direction D1, the unit film package regions UFPR may be positioned between opposite ends of the first dummy lines 440. Alternatively, as shown in FIG. 8, the first dummy lines 440 may extend in the first direction D1 on the peripheral regions 100PR of the film substrate 100, and a plurality of unit film package regions UFPR may be positioned on the inner region 100CR between the first dummy lines 440.

The second dummy lines 460 may be disposed on the front surface 100u of the film substrate 100. The second dummy lines 460 may be provided in the first direction D1 from the unit film package region UFPR of one unit film package 10. On the inner regions 100CR, the second dummy lines 460 may be disposed between the first dummy lines 440. The second dummy lines 460 may be separately provided on one side of each of the unit film package regions UFPR.

The second solder resist layers 520 may each be disposed in the second direction D2 or its opposite direction from the first solder resist layer 510. A length in the first direction D1 of each of the second solder resist layers 520 may be greater than that of the first solder resist layer 510. For example, when viewed in the first direction D1, the unit film package regions UFPR may be positioned between opposite ends of the second solder resist layers 520. As shown in the embodiment of FIG. 8, when the unit film package regions UFPR share the same first dummy lines 440, the second solder resist layers 520 may cover the first dummy lines 440, while extending in the first direction D1 on the peripheral regions 100PR of the film substrate 100.

The first extension parts 515 may be positioned between the first solder resist layer 510 and the second solder resist layers 520. The first extension parts 515 may extend from the peripheral regions 100PR toward the inner region 100CR, and may run across the cut line CL to extend onto the mounting region MR. The protection layer 500 may include portions provided on the cut line CL so as to connect the first solder resist layer 510 to the second solder resist layers 520, and the first extension parts 515 may be the portions of the protection layer 500.

The second extension part 525 may be positioned in a direction opposite to the first direction D1 from the first solder resist layer 510. For example, the second extension part 525 may be positioned between the unit film package region UFPR and the test pads 330. The second extension part 525 may extend in the second direction D2 and be connected to the second solder resist layers 520. The second extension part 525 may be portions of the protection layer 500 that are provided for connection of the second solder resist layers 520.

The third extension part 535 may be positioned in the first direction D1 from the first solder resist layer 510. The third extension part 535 may cover the second dummy lines 460. The third extension part 535 may extend in the second direction D2 and be connected to the second solder resist layers 520. The third extension part 535 may be portions of the protection layer 500 that are provided for connection of the second solder resist layers 520.

Based on shapes of the first solder resist layer 510, the second solder resist layers 520, the first extension parts 515, and the second extension part 525, the protection layer 500 may have a planar shape having openings that cover the unit film package 10, the first dummy lines 440, the second dummy lines 460, and the test connection lines 450 and that expose the first connection pads 310 and the second connection pads 320.

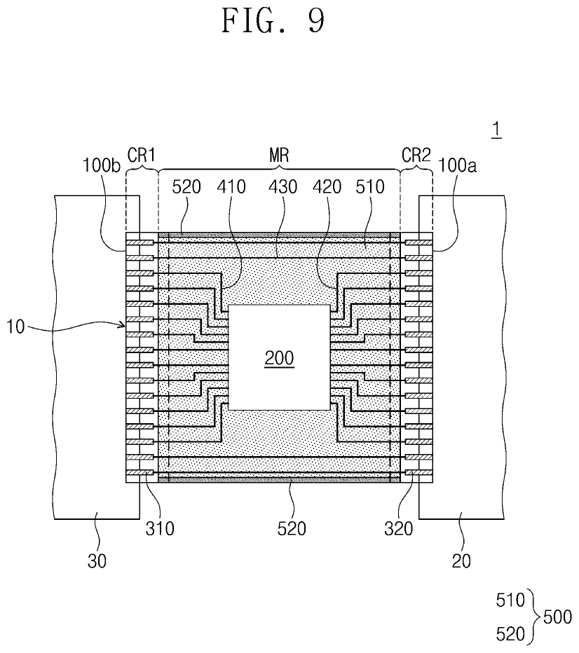

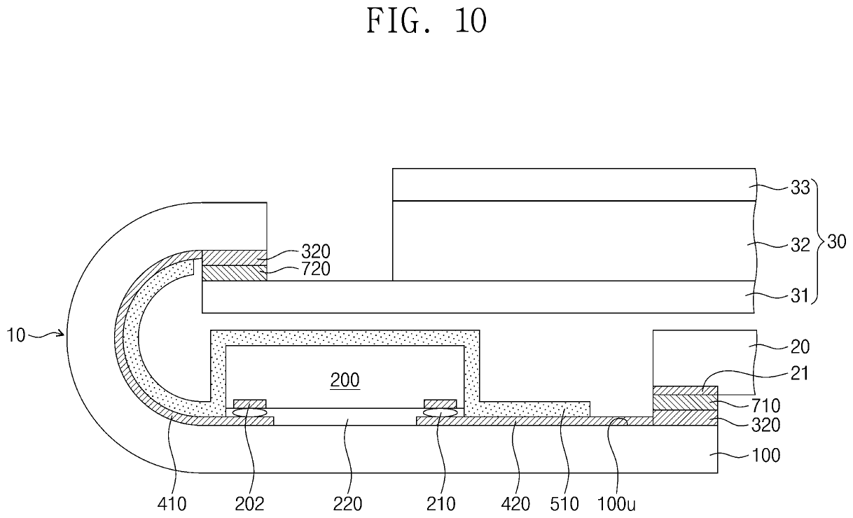

FIG. 9 is a plan view showing a semiconductor package module according to some embodiments of the present inventive concepts. FIG. 10 is a cross-sectional view showing a semiconductor package module according to some embodiments of the present inventive concepts.

Referring to FIGS. 9 and 10, a package module 1 may include a unit film package 10, a circuit board 20, and a display device 30. The package module 1 may be a display device assembly. The package module 1 may be fabricated by using at least one of the film packages FPKG discussed with reference to FIGS. 1A to 1D, FIG. 2, FIGS. 3A to 3D, FIGS. 4A to 4D, FIG. 5, FIGS. 6A to 6D, FIGS. 7A to 7D, and FIG. 8. Referring back to FIGS. 1A to 1D, the film package FPKG may be cut along the cut line CL to form a plurality of unit film packages 10 that are separated from each other. A separate process may separate the unit film package 10 from the film package FPKG, and in this process, the unit film package regions UFPR may be separated along the cut line CL from the film substrate 100. The unit film packages 10 may include components on the unit film package regions UFPR of the film substrate 100. For example, each of the unit film packages 10 may include a film substrate 100, a semiconductor chip 200, first connection lines 410, second connection lines 420, the third connection lines 430, first connection pads 310, second connection pads 320, and a protection layer 500. In each of the unit film packages 10, an outer boundary of the film substrate 100 may correspond to the cut line CL. Differently from that shown, the unit film packages 10 may be fabricated by using at least one of the film packages FPKG discussed with reference to FIG. 2, FIGS. 3A to 3D, FIGS. 4A to 4D, FIG. 5, FIGS. 6A to 6D, FIGS. 7A to 7D, and FIG. 8. The following description will focus on a single unit film package 10.

The circuit board 20 and the display device 30 may be respectively mounted on a first end 100a and a second end 100b of the film substrate 100 of the unit film package 10, with the result that the package module 1 may be fabricated. Based on FIGS. 1A to 1D, the first end 100a of the film substrate 100 may be an end in the first direction D1 of the film substrate 100, and the second end 100b of the film substrate 100 may be an end in a direction opposite to the first direction D1 of the film substrate 100. For example, the film substrate 100 may include an end on which the second connection pads 320 are provided and which corresponds to the first end 100a of the film substrate 100, and may also include an end on which the first connection pads 310 are provided and which corresponds to the second end 100b of the film substrate 100. As shown in FIG. 10, the film substrate 100 may be flexible and bendable. For example, a portion of the front surface 100u (or a top surface) of the film substrate 100, which has the semiconductor chip 200 provided on the top surface 100u, may face another portion of the top surface 100u of the film substrate 100.

The circuit board 20 may be disposed on the top surface 100u of the film substrate 100. The circuit board 20 may be adjacent to the first end 100a of the film substrate 100. For example, the circuit board 20 may include a printed circuit board (PCB) or a flexible printed circuit board (FPCB). The protection layer 500 discussed with reference to FIGS. 1A to 1D may expose the second connection pads 320. Input connectors 710 may be provided between the second connection pads 320 and pads 21 of the circuit board 20. The input connectors 710 may include an anisotropic conductive film (ACF). Alternatively, the input connectors 710 may include a solder ball or a solder bump. As shown in FIG. 10, the circuit board 20 may be electrically connected through the input connectors 710 to the second connection pads 320. The circuit board 20 may be electrically connected to the semiconductor chip 200 through the second connection pads 320 and the second connection lines 420.

The display device 30 may be disposed on the top surface 100u of the film substrate 100. The display device 30 may be adjacent to the second end 100b of the film substrate 100. The display device 30 may include a display substrate 31, a display panel 32, and a protector 33 that are stacked. Output connectors 720 may be provided between the display substrate 31 and the first connection pads 310. The output connectors 720 may be an anisotropic conductive film. Alternatively, the output connectors 720 may include a solder ball or a solder bump. As shown in FIG. 10, the display substrate 31 may be electrically connected through the output connectors 720 to the semiconductor chip 200. The display device 30 may be electrically connected to the semiconductor chip 200 through the first connection pads 310 and the first connection lines 410.

The semiconductor chip 200 may receive signals through the second connection lines 420 from the circuit board 20. The semiconductor chip 200 may include driving integrated circuits (e.g., gate driving integrated circuit and/or data driving integrated circuit), and may generate driving signals (e.g., gate driving signal and/or data driving signal). The driving signal generated from the semiconductor chip 200 may be supplied through the first connection lines 410 to a gate line and/or a data line of the display substrate 31. The display panel 32 may therefore operate. According to some embodiments, the semiconductor chip 200 may be provided in plural.

In a semiconductor package according to some embodiments of the present inventive concepts, as dummy lines are disposed on peripheral regions where neither connection lines nor pads are provided, peripheral regions of a film substrate might not be easily deformed. In addition, as a protection layer is disposed on a unit film package and dummy lines and also on a cut line, the film substrate might not be easily deformed in the vicinity of the cut line. Therefore, a film package may be prevented from being deformed in a width direction, not a longitudinal direction, and the film package and the unit film package may increase in structural stability.

Moreover, as dummy lines extending a width direction are disposed on one side of unit film package regions, the film package may be prevented from being deformed in a width direction, not a longitudinal direction, and the film package and the unit film package may increase in structural stability. Furthermore, as second solder resist layers and a second extension part surround the unit film package region, the film substrate might not be easily deformed in the vicinity of the unit film package region and the unit film package. Accordingly, the film package may be prevented from being deformed, and the film package and the unit film package may increase in structural stability.

Although the present inventive concepts have been described in connection with embodiments of the present inventive concepts illustrated in the accompanying drawings, it will be understood by one of ordinary skill in the art that variations in form and detail may be made therein without departing from the spirit and essential feature of the present disclosure.

1. A semiconductor package, comprising:
a base film including peripheral regions and an inner region disposed between the peripheral regions, the peripheral regions extending in a longitudinal direction and the inner region extending in the longitudinal direction;
a unit film package disposed on the inner region of the base film and defined by a cut line;
dummy patterns disposed on the peripheral regions of the base film and disposed between the cut line and opposite ends of the base film in the width direction; and
a first solder resist layer disposed on the base film, the first solder resist layer covering the unit film package inside the cut line,
wherein the first solder resist layer extends in the width direction, runs across the cut line and covers the dummy patterns.

2. The semiconductor package of claim 1, further comprising a second solder resist layer disposed on the inner region of the base film and spaced apart in the longitudinal direction from one side of the cut line,
wherein the second solder resist layer extends in the width direction toward the peripheral regions and is connected to the first solder resist layer.

3. The semiconductor package of claim 2, wherein
the second solder resist layer is provided in plural, and
the plurality of second solder resist layers are spaced apart in the longitudinal direction from opposite ends of the cut line.

4. The semiconductor package of claim 2, further comprising test pads disposed on the inner region of the base film and spaced apart in the longitudinal direction from the one side of the cut line,
wherein the second solder resist layer is disposed between the test pads and the cut line.

5. The semiconductor package of claim 2, wherein the first solder resist layer and the second solder resist layer are connected to each other and constitute a single layer.

6. The semiconductor package of claim 1, wherein a distance in the width direction between the cut line and the opposite ends of the base film is in a range of about 4.5 mm to about 50 mm.

7. The semiconductor package of claim 1, wherein
the base film includes sprocket holes on the peripheral regions and is arranged at a regular interval in the longitudinal direction, and
the first solder resist layer is spaced apart in the width direction from the sprocket holes.

8. The semiconductor package of claim 1, wherein the unit film package includes:
a mounting region disposed on the inner region; and
a connection region provided in the longitudinal direction from the mounting region,
wherein, in the width direction, a first width of the mounting region is less than a second width of the connection region.

9. The semiconductor package of claim 8, wherein the unit film package has an H shape when, in a plan view.

10. The semiconductor package of claim 1, wherein the unit film package includes:
a mounting region disposed on the inner region; and
a connection region provided in the longitudinal direction from the mounting region,
wherein, in the width direction, a first width of the mounting region is equal to a second width of the connection region.

11-12. (canceled)

13. A semiconductor package, comprising:
a base film that extends in a first direction and includes a first peripheral region, an inner region, and a second peripheral region that are arranged in a second direction orthogonal to the first direction, wherein the first peripheral region, the inner region, and the second peripheral region extend in the second direction;
a unit film package disposed on the inner region of the base film and defined by a cut line;
a first dummy pattern and a second dummy pattern respectively provided on the first peripheral region and the second peripheral region of the base film, wherein each of the first and second dummy patterns is disposed between the cut line and one of opposite ends in the second direction of the base film;
a first solder resist layer disposed on the base film, the first solder resist layer covering the unit film package inside the cut line;
a second solder resist layer that covers the first dummy pattern on the first peripheral region of the base film; and
a third solder resist layer that covers the second dummy pattern on the second peripheral region of the base film,
wherein the second solder resist layer and the third solder resist layer are connected to each other through a first extension part that is spaced apart in the first direction from the cut line and extends in the second direction to connect the second solder resist layer to the third solder resist layer.

14. The semiconductor package of claim 13, further comprising a second extension part that extends in a direction that is opposite to the first direction and connects the second solder resist layer to the third solder resist layer.

15. The semiconductor package of claim 13, further comprising test pads disposed on the inner region of the base film and spaced apart in the first direction from the cut line,
wherein the first extension part is disposed between the test pads and the cut line.

16. The semiconductor package of claim 13, further comprising:
a third extension part that runs in the second direction from the second solder resist layer across the cut line and is connected to the first solder resist layer; and
a fourth extension part that runs in a direction opposite to the second direction from the third solder resist layer across the cut line and is connected to the first solder resist layer.

17. (canceled)

18. The semiconductor package of claim 13, wherein
the base film includes sprocket holes on the peripheral regions and is arranged at a regular interval in the first direction, and
the first solder resist layer is spaced apart in the second direction from the sprocket holes.

19. The semiconductor package of claim 13, wherein the unit film package includes:
a semiconductor chip disposed on a mounting region on the inner region;
pads on connection regions disposed on opposite sides in the first direction from the mounting region, the pad being arranged in the second direction; and
connection lines through which the semiconductor chip and the pads are connected to each other on the base film.

20. The semiconductor package of claim 19, wherein
in the second direction, a first width of the mounting region is less than a second width of the connection region, and
the unit film package has an H shape, in a plan view.

21. The semiconductor package of claim 19, wherein
in the second direction, a first width of the mounting region is equal to a second width of the connection region, and
the unit film package has a tetragonal shape, a plan view.

22. The semiconductor package of claim 19, wherein one of the connection regions is disposed between the first solder resist layer and the first extension part.

23. A semiconductor package, comprising:
a base film including an inner region, a first peripheral region, and a second peripheral region, the inner region extending in a longitudinal direction, and the first peripheral region and the second peripheral region being respectively disposed on opposite ends in a width direction of the base film;
a unit film package disposed on the inner region of the base film and defined by a cut line;
a first dummy pattern disposed on the first peripheral region of the base film and disposed between the cut line and one of the opposite ends of the base film;
a second dummy pattern disposed on the second peripheral region of the base film and disposed between the cut line and the other of the opposite ends of the base film;
a first solder resist layer disposed on the base film, the first solder resist layer covering the unit film package inside the cut line;
a second solder resist layer covering the first dummy pattern on the first peripheral region of the base film; and
a third solder resist layer covering the second dummy pattern on the second peripheral region of the base film,
wherein the second solder resist layer and the third solder resist layer are connected to each other through an extension part that extends in the width direction, and
wherein the unit film package includes:
a mounting region disposed on the inner region; and
connection regions disposed on opposite ends in the longitudinal direction from the mounting region.

24-33. (canceled)
